(19) United States
(12) Patent Application Publication
(10) Pub. No.: US 2018/0053776 A1
(43) Pub. Date: Feb. 22, 2018

(54) MEMORY DEVICE AND METHOD FOR MANUFACTURING THE SAME

(71) Applicant: Vanguard International Semiconductor Corporation, Hsinchu (TW)

(72) Inventors: Chi-Nan CHEN, Lukang Township (TW); Jen-Chuan PAN, Hsinchu City (TW)

(73) Assignee: Vanguard International Semiconductor Corporation, Hsinchu (TW)

(21) Appl. No.: 15/237,828

(22) Filed: Aug. 16, 2016

(51) Int. Cl. H01L 27/115; H01L 29/788; H01L 23/528

(52) U.S. Cl. CPC H01L 27/11568; H01L 23/5283; H01L 29/7883; H01L 27/11521

(57) ABSTRACT

A memory device is provided. The memory device includes a substrate and a first stack structure. The first stack structure includes a tunneling layer. The tunneling layer includes SiₓO_{y}N_{z}, wherein x:y is 1:0.1 to 1:10, and x:z is 1:0.1 to 1:10. The first stack structure further includes a charge layer disposed over the tunneling layer and a first silicon oxide layer disposed over the charge layer. The first stack structure further includes a first gate line disposed over the first silicon oxide layer. The memory device further includes a source line doped region disposed in the substrate and disposed at the first side of the first stack structure. The memory device further includes a bit line doped region disposed in the substrate and disposed at the second side of the first stack structure. A method for manufacturing the memory device is also provided.

### BACKGROUND OF THE INVENTION

### Field of the Invention

The disclosure relates to a memory device and a method for manufacturing the same, and in particular to a non-volatile memory device and a method for manufacturing the same.

### Description of the Related Art

Electronic devices presently on the market, such as notebook computers, include memory devices to store data. These memory devices may be non-volatile memory device. A non-volatile memory device maintains stored data when it is not connected to a power source. There are many types of non-volatile memory, including read-only memory (ROM), electronic erasable programmable read-only memory (EEPROM), and flash memory.

However, existing memory devices have not been satisfactory in every respect. Therefore, a memory device which may further decrease the programming voltage (or write voltage), improve the program speed (or write speed) and lengthen the data storage time is needed. In addition, a method for manufacturing the memory device is also needed.

### BRIEF SUMMARY OF THE INVENTION

The present disclosure provides a memory device, including: a substrate; a first stack structure disposed over a top surface of the substrate, wherein the first stack structure has a first side and a second side opposite to each other, and the first stack structure includes: a tunneling layer disposed over the top surface of the substrate, wherein the tunneling layer includes SiₓO_{y}N_{z}, wherein x:y ranges from about 1:0.1 to 1:10, and x:z ranges from about 1:0.1 to 1:10; a charge layer disposed over the tunneling layer; a first silicon oxide layer disposed over the charge layer; and a first gate line disposed over the first silicon oxide layer; a source line doped region disposed in the substrate and disposed at the first side of the first stack structure; and a bit line doped region disposed in the substrate and disposed at the second side of the first stack structure.

The present disclosure also provides a method for manufacturing a memory device, including: providing a substrate; forming a first stack structure over a top surface of the substrate, wherein the first stack structure has a first side and a second side opposite to each other, and the first stack structure includes: a tunneling layer disposed over the top surface of the substrate, wherein the tunneling layer includes SiₓO_{y}N_{z}, wherein x:y ranges from about 1:0.1 to 1:10, and x:z ranges from about 1:0.1 to 1:10; a charge layer disposed over the tunneling layer; a first silicon oxide layer disposed over the charge layer; and a first gate line disposed over the first silicon oxide layer; forming a source line doped region in the substrate, wherein the source line doped region is disposed at the first side of the first stack structure; and forming a bit line doped region in the substrate, wherein the bit line doped region is disposed at the second side of the first stack structure.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 is a cross-sectional view of a memory device in accordance with some embodiments of the present disclosure;

FIG. 2 is a cross-sectional view of a memory device in accordance with some embodiments of the present disclosure; and

FIG. 3 is a cross-sectional view of a memory device in accordance with some embodiments of the present disclosure.

### DETAILED DESCRIPTION OF THE INVENTION

The memory device of the present disclosure and the method for manufacturing this memory device are described in detail in the following description. In the following detailed description, for purposes of explanation, numerous specific details and embodiments are set forth in order to provide a thorough understanding of the present disclosure. The specific elements and configurations described in the following detailed description are set forth in order to clearly describe the present disclosure. It will be apparent, however, that the exemplary embodiments set forth herein are used merely for the purpose of illustration, and the inventive concept may be embodied in various forms without being limited to those exemplary embodiments. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments. In addition, in this specification, expressions such as “first material layer disposed on/over a second material layer”, may indicate the direct contact of the first material layer and the second material layer, or it may indicate a non-contact state with one or more intermediate layers between the first material layer and the second material layer. In the above situation, the first material layer may not be in direct contact with the second material layer.

In addition, in this specification, relative expressions are used. For example, “lower”, “bottom”, “higher” or “top” are used to describe the position of one element relative to another. It should be appreciated that if a device is flipped upside down, an element that is “lower” will become an element that is “higher”.

The terms “about” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. When there is no specific description, the stated value includes the meaning of “about” or “substantially”.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another region, layer or section. Thus, a first element, component, region, layer, portion or section discussed below could be termed a second element, component, region, layer, portion or section without departing from the teachings of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

This description of the exemplary embodiments is intended to be read in connection with the accompanying drawings, which are to be considered part of the entire written description. The drawings are not drawn to scale. In addition, structures and devices are shown schematically in order to simplify the drawing.

In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

The term “substrate” is meant to include devices formed within a semiconductor wafer and the layers overlying the wafer. All semiconductor element needed may be already formed over the substrate. However, the substrate is represented with a flat surface in order to simplify the drawing. The term “substrate surface” is meant to include the uppermost exposed layers on a semiconductor wafer, such as silicon surface, and insulating layer and/or metallurgy lines.

The data storage structure of some embodiments of the present disclosure includes a three-layered structure including a tunneling layer, a charge layer and a silicon oxide layer. In addition, the tunneling layer includes specific material such that the memory device of some embodiments of the present disclosure (such as a non-volatile memory device) may further decrease the programming voltage (or write voltage), improve the program speed (or write speed) and lengthen the data storage time.

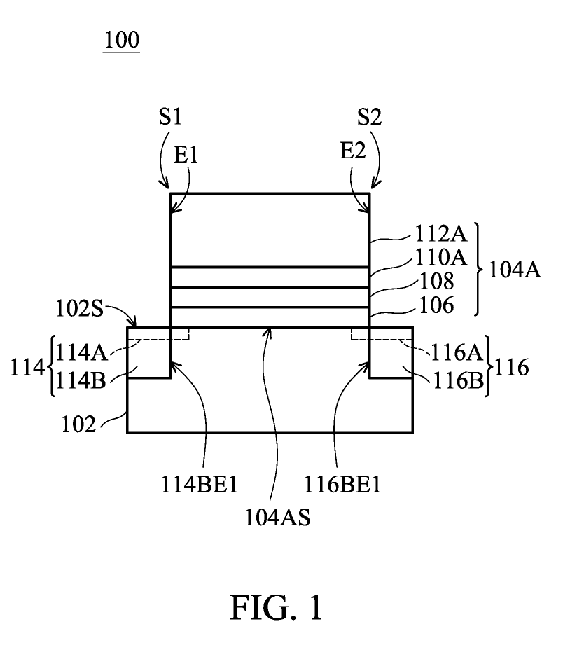

FIG. 1 is a cross-sectional view of a memory device 100 in accordance with some embodiments of the present disclosure. In some embodiments of the present disclosure, the memory device 100 may include a non-volatile memory device. In addition, in some embodiments of the present disclosure, the memory device 100 may be manufactured using the following steps.

Referring to FIG. 1, a substrate 102 is provided first. The substrate 102 may include, but is not limited to, semiconductor substrate such as a silicon substrate. In addition, the substrate 102 may include an element semiconductor which may include germanium; a compound semiconductor which may include gallium nitride (GaN), silicon carbide, gallium arsenide, gallium phosphide, indium phosphide, indium arsenide and/or indium antimonide; an alloy semiconductor which may include SiGe alloy, GaAsP alloy, AlInAs alloy, AlGaAs alloy, GaInAs alloy, GaInP alloy and/or GaInAsP alloy; or a combination thereof. In addition, the substrate 102 may include a semiconductor-on-insulator. In some embodiments of the present disclosure, the substrate 102 may be lightly doped with a first conductive type dopant. The substrate 102 may be a lightly-doped P-type or N-type substrate.

In the described embodiments, the term “lightly doped” means an impurity concentration within about 10¹¹/cm³ to about 10¹³/cm³, for example about 10¹²/cm³. One skilled in the art will recognize, however, that “lightly doped” is a term of art that depends upon the specific device type, technology generation, minimum feature size, and the like. It is intended, therefore, that the term be interpreted in light of the technology being evaluated and not be limited to the described embodiments.

Subsequently, a first stack structure 104A is formed over the top surface 102S of the substrate 102. The first stack structure 104A serves as the data storage structure of the memory device 100. The first stack structure 104A has a first side S1 and a second side S2 opposite to each other. The first stack structure 104A has a first edge E1 at the first side S1, and has a second edge E2 at the second side S2.

The first stack structure 104A includes a tunneling layer 106 disposed over the top surface 102S of the substrate 102, a charge layer 108 disposed over the tunneling layer 106, a first silicon oxide layer 110A disposed over the charge layer 108, and a first gate line 112A disposed over the first silicon oxide layer 110A. The charge layer 108 is used to store data (i.e. electron or electron hole). The first silicon oxide layer 110A is used to prevent the electron or electron hole in the charge layer 108 from entering the first gate line 112A. In some embodiments of the present disclosure, the charge layer 108 may be a silicon nitride layer.

In some embodiments of the present disclosure, the material of the tunneling layer 106 includes SiₓO_{y}N_{z}, wherein x:y ranges from about 1:0.1 to 1:10, for example from about 1:0.5 to 1:8, or about 1:1 to 1:5, or about 1:2 to 1:3, and x:z ranges from about 1:0.1 to 1:10, for example from about 1:0.5 to 1:8, or about 1:1 to 1:5, or about 1:2 to 1:3. In some embodiments of the present disclosure, y is 0, and x:y is about 3:4. In other words, the material of the tunneling layer 106 includes Si₃N₄.

In some embodiments of the present disclosure, the material of the charge layer 108 includes SiₐN_{b}, wherein a:b ranges from about 1:0.1 to 1:10, for example from about 1:0.5 to 1:8, or about 1:1 to 1:5, or about 1:2 to 1:3. In some embodiments of the present disclosure, a:b is about 3:4. In other words, the material of the charge layer 108 includes Si₃N₄.

In addition, the tunneling layer 106 and the charge layer 108 are two independent and different layers. There is an interface between the tunneling layer 106 and the charge layer 108. For example, in some embodiments of the present disclosure, when y is 0, the tunneling layer 106 is SiₓN_{z}, and the charge layer 108 is SiₐN_{b}, and x:z is not equal to a:b.

When programming data, the carrier (i.e. electron or electron hole) will penetrate the tunneling layer 106, then enter and be stored in the charge layer 108. The charge layer 108 is used to prevent the carrier from entering the first gate line 112A. Since the tunneling layer 106 in some embodiments of the present disclosure includes SiₓO_{y}N_{z} which has small band gap, it is easier for the carrier to penetrate the tunneling layer 106 and enter the charge layer 108 when programming data. Therefore, the programming voltage (or write voltage) may be decreased further, and the program speed (or write speed) may be improved. In addition, since there is an interface between the charge layer 108 and the tunneling layer 106, this interface may prevent the carriers which have entered the charge layer 108 from penetrating the tunneling layer 106 and back to the substrate 102 in the data storage period, which in turn lengthens the data storage time.

In some embodiments of the present disclosure, the material of the first silicon oxide layer 110A may include, but is not limited to, silicon dioxide. In some embodiments of the present disclosure, the material of the first gate line 112A may include, but is not limited to, amorphous-silicon, poly-silicon, one or more metal, metal nitride, conductive metal oxide, or a combination thereof. The metal may include, but is not limited to, molybdenum, tungsten, titanium, tantalum, platinum, or hafnium. The metal nitride may include, but is not limited to, molybdenum nitride, tungsten nitride, titanium nitride or tantalum nitride. The conductive metal oxide may include, but is not limited to, ruthenium oxide or indium tin oxide.

In some embodiments of the present disclosure, the thickness of the tunneling layer 106 ranges from about 2 nm-200 nm, for example from about 5 nm-150 nm, or about 10 nm-100 nm, or about 30 nm-80 nm. In addition, the tunneling layer 106 may be in direct contact with the charge layer 108.

In some embodiments of the present disclosure, the thickness of the charge layer 108 ranges from about 2 nm-200 nm, for example from about 5 nm-150 nm, or about 10 nm-100 nm, or about 30 nm-80 nm. In addition, the charge layer 108 may be in direct contact with the first silicon oxide layer 110A.

In some embodiments of the present disclosure, the thickness of the first silicon oxide layer 110A ranges from about 2 nm-200 nm, for example from about 5 nm-150 nm, or about 10 nm-100 nm, or about 30 nm-80 nm. In addition, the first silicon oxide layer 110A may be in direct contact with the first gate line 112A. In some embodiments of the present disclosure, the thickness of the first gate line 112A ranges from about 50 nm-2000 nm, for example from about 100 nm-500 nm. In addition, the thickness of the first gate line 112A is greater than the thickness of the tunneling layer 106, the thickness of the charge layer 108, or the thickness of the first silicon oxide layer 110A.

In some embodiments of the present disclosure, the first stack structure 104A may be formed by the following steps. First, a tunneling material layer (used to form the tunneling layer 106), a charge material layer (used to form the charge layer 108) and a first silicon oxide material layer (used to form the first silicon oxide layer 110A) are sequentially formed over the top surface 102S of the substrate 102 blanketly by the chemical vapor deposition or spin-on coating. The chemical vapor deposition may include, but is not limited to, low pressure chemical vapor deposition (LPCVD), low temperature chemical vapor deposition (LTCVD), rapid thermal chemical vapor deposition (RTCVD), plasma enhanced chemical vapor deposition (PECVD), atomic layer deposition (ALD), or any other suitable method.

In some embodiments of the present disclosure, the ratio of the x, y, z of SiₓO_{y}N_{z} in the tunneling material layer (used to form the tunneling layer 106) may be fine-tuned by adjusting the ratio of each gas in the chemical vapor deposition, and therefore the ratio of silicon, oxygen and nitrogen in the tunneling layer 106 may be fine-tuned. In addition, the ratio of the a and b of SiₐN_{b} in the charge material layer (used to form the charge layer 108) may be fine-tuned by adjusting the ratio of each gas in the chemical vapor deposition, and therefore the ratio of silicon and nitrogen in the charge layer 108 may be fine-tuned.

Subsequently, a first gate line material layer (used to form the first gate line 112A) is blanketly deposited over the first silicon oxide material layer by chemical vapor deposition (CVD), sputtering, resistive thermal evaporation, electron beam evaporation, or any other suitable method, as previously described. For example, in one embodiment, the amorphous silicon conductive material layer or poly-silicon conductive material layer may be deposited and formed by low-pressure chemical vapor deposition at about 525° C.˜650° C. The thickness of the amorphous silicon conductive material layer or poly-silicon conductive material layer may range from about 1000 Å to 10000 Å.

Subsequently, the first gate line material layer, the first silicon oxide material layer, the charge material layer and the tunneling material layer are etched by one or more etching processes to form the first gate line 112A, the first silicon oxide layer 110A, the charge layer 108, and the tunneling layer 106.

The etching process may include wet etch, dry etch, or a combination thereof. The wet etch may include, but is not limited to, immersion etching, spray etching, or any other suitable etching process, or a combination thereof. The dry etch may include, but is not limited to, capacitively coupled plasma etching, inductively coupled plasma etching, helicon plasma etching, electron cyclotron resonance plasma etching or any other suitable dry etching process, or a combination thereof. The dry etching process employs a process gas, which may include, but is not limited to, inert gas, fluorine-containing gas, chlorine-containing gas, bromine-containing gas, iodine-containing gas, a combination thereof or any other suitable gases. In some embodiments of the present disclosure, the processing gas may include, but is not limited to, Ar, CF₄, SF₆, CH₂F₂, CHF₃, C₂F₆, Cl₂, CHCl₃, CCl₄, HBr, CHBr₃, BF₃, BCl₃, a combination thereof or any other suitable gases.

Subsequently, still referring to FIG. 1, a source line doped region 114 is formed in the substrate 102. In addition, the source line doped region 114 is disposed at the first side S1 of the first stack structure 104A. The source line doped region 114 has a second conductive type, and the second conductive type is different from the first conductive type of the substrate 102. For example, in some embodiments of the present disclosure, the first conductive type is P-type, whereas the second conductive type is N-type. However, in other embodiments of the present disclosure, the first conductive type is N-type, whereas the second conductive type is P-type.

Still referring to FIG. 1, in some embodiments of the present disclosure, the source line doped region 114 includes a lightly-doped region 114A disposed in the substrate 102 and a heavily-doped region 114B partially overlapping with the lightly-doped region 114A.

In some embodiments of the present disclosure, the doping concentration of the lightly-doped region 114A is about 10¹¹-10¹³/cm³, for example about 10¹²/cm³. In addition, the doping concentration of the heavily-doped region 114B is greater than 10¹³/cm³, for example about 10¹⁵-10¹⁷/cm³.

In some embodiments of the present disclosure, the source line doped region 114 may be formed by ion implantation. For example, when the second conductive type is N-type, the predetermined region for the source line doped region 114 may be implanted with phosphorous ions or arsenic ions to form the source line doped region 114. In other embodiments of the present disclosure, when the first conductive type is P-type, the predetermined region for the source line doped region 114 may be implanted with boron ion, indium ion or boron difluoride ion (BF₂⁺) to form the source line doped region 114.

Still referring to FIG. 1, in some embodiments of the present disclosure, the lightly-doped region 114A extends under the bottom surface 104AS of the first stack structure 104A. In addition, in some embodiments of the present disclosure, the lightly-doped region 114A may be in direct contact with the bottom surface 104AS of the first stack structure 104A. In some embodiments of the present disclosure, the heavily-doped region 114B partially overlaps with the lightly-doped region 114A. In addition, the depth of the heavily-doped region 114B is greater than the depth of the lightly-doped region 114A.

In addition, in some embodiments of the present disclosure, the heavily-doped region 114B does not extend under the bottom surface 104AS of the first stack structure 104A. In other words, the heavily-doped region 114B does not come into contact with the bottom surface 104AS of the first stack structure 104A. In addition, in some embodiments of the present disclosure, the edge 114BE1 of the heavily-doped region 114B aligns with the first edge E1 of the first stack structure 104A.

Subsequently, still referring to FIG. 1, a bit line doped region 116 is formed in the substrate 102. In addition, the bit line doped region 116 is disposed at the second side S2 of the first stack structure 104A. The bit line doped region 116 has a second conductive type, and the second conductive type is different from the first conductive type of the substrate 102. For example, in some embodiments of the present disclosure, the first conductive type is P-type, whereas the second conductive type is N-type. However, in other embodiments of the present disclosure, the first conductive type is N-type, whereas the second conductive type is P-type.

Still referring to FIG. 1, in some embodiments of the present disclosure, the bit line doped region 116 includes a lightly-doped region 116A disposed in the substrate 102 and a heavily-doped region 116B partially overlapping with the lightly-doped region 116A.

In some embodiments of the present disclosure, the doping concentration of the lightly-doped region 116A is about 10¹¹-10¹³/cm³, for example about 10¹²/cm³. In addition, the doping concentration of the heavily-doped region 116B is greater than 10¹³/cm³, for example about 10¹⁵-10¹⁷/cm³.

In some embodiments of the present disclosure, the bit line doped region 116 may be formed by ion implantation. For example, when the second conductive type is N-type, the predetermined region for the bit line doped region 116 may be implanted with phosphorous ions or arsenic ions to form the bit line doped region 116. In other embodiments of the present disclosure, when the first conductive type is P-type, the predetermined region for the bit line doped region 116 may be implanted with boron ion, indium ion or boron difluoride ion (BF₂⁺) to form the bit line doped region 116. In addition, in some embodiments of the present disclosure, the bit line doped region 116 and the source line doped region 114 may be formed in the same manufacturing process.

Still referring to FIG. 1, in some embodiments of the present disclosure, the lightly-doped region 116A extends under the bottom surface 104AS of the first stack structure 104A. In addition, in some embodiments of the present disclosure, the lightly-doped region 116A may be in direct contact with the bottom surface 104AS of the first stack structure 104A. In some embodiments of the present disclosure, the heavily-doped region 116B partially overlaps with the lightly-doped region 116A. In addition, the depth of the heavily-doped region 116B is greater than the depth of the lightly-doped region 116A.

In addition, in some embodiments of the present disclosure, the heavily-doped region 116B does not extend under the bottom surface 104AS of the first stack structure 104A. In other words, the heavily-doped region 116B does not come into contact with the bottom surface 104AS of the first stack structure 104A. In addition, in some embodiments of the present disclosure, the edge 116BE1 of the heavily-doped region 116B aligns with the second edge E2 of the first stack structure 104A.

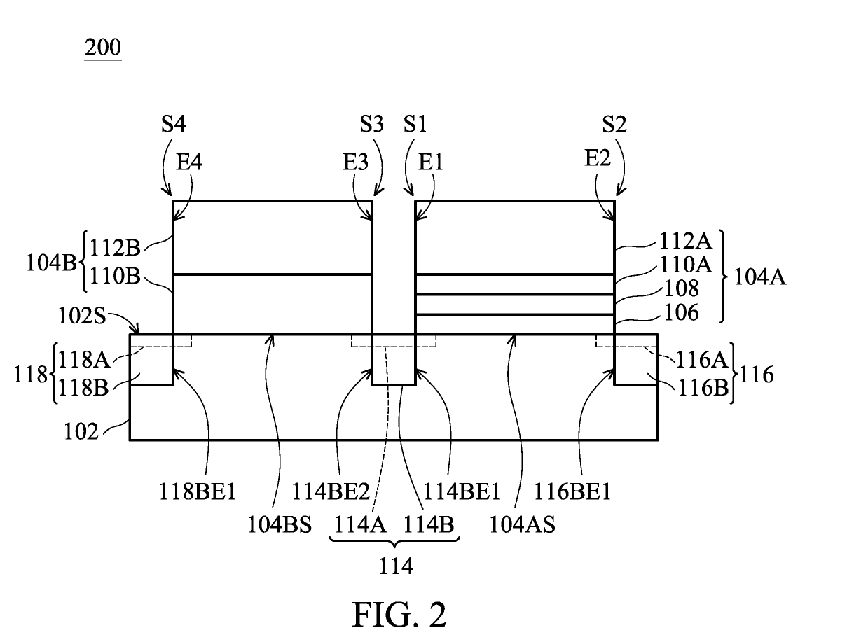

FIG. 2 is a cross-sectional view of a memory device 200 in accordance with some other embodiments of the present disclosure. As shown in FIG. 2, a second stack structure 104B may be further formed over the top surface 102S of the substrate 102. In addition, the second stack structure 104B is disposed at the first side S1 of the first stack structure 104A.

As shown in FIG. 2, the second stack structure 104B includes a second silicon oxide layer 110B disposed over the top surface 102S of the substrate 102, and a second gate line 112B disposed over the second silicon oxide layer 110B. The second silicon oxide layer 110B and the second gate line 112B may be formed by steps that are similar to those mentioned above. In other words, in some embodiments of the present disclosure, the second silicon oxide layer 110B may be formed by the chemical vapor deposition or spin-on coating. The second gate line 112B may be formed by chemical vapor deposition (CVD), sputtering, resistive thermal evaporation, electron beam evaporation, or any other suitable methods.

In addition, in some embodiments of the present disclosure, the thickness of the second silicon oxide layer 110B is substantially equal to the total thickness of the tunneling layer 106, the charge layer 108, and the first silicon oxide layer 110A of the first stack structure 104A.

In addition, the second stack structure 104B has a third side S3 and a fourth side S4 opposite to each other. The third side S3 faces the first side S1 of the first stack structure 104A. The second stack structure 104B has a third edge E3 at the third side S3, and has a fourth edge E4 at the fourth side S4.

In addition, in some embodiments of the present disclosure, as shown in FIG. 2, the source line doped region 114, which is disposed at the first side S1 of the first stack structure 104A, extends from the bottom surface 104AS of the first stack structure 104A to the bottom surface 104BS of the second stack structure 104B. Therefore, in some embodiments of the present disclosure, the source line doped region 114 also serves as a bit line doped region of the second stack structure 104B.

In particular, the lightly-doped region 114A of the source line doped region 114 extends from the bottom surface 104AS of the first stack structure 104A adjacent to the first side S1 to the bottom surface 104BS of the second stack structure 104B adjacent to the third side S3. The lightly-doped region 114A may be in direct contact with the bottom surface 104AS of the first stack structure 104A and the bottom surface 104BS of the second stack structure 104B.

In addition, the heavily-doped region 114B of the source line doped region 114 does not extend under the bottom surface 104AS of the first stack structure 104A and the bottom surface 104BS of the second stack structure 104B. In other words, the heavily-doped region 114B does not come into contact with the bottom surface 104AS of the first stack structure 104A and the bottom surface 104BS of the second stack structure 104B. In addition, in some embodiments of the present disclosure, one edge 114BE1 of the heavily-doped region 114B is aligned with the first edge E1 of the first stack structure 104A, and the other edge 114BE2 of the heavily-doped region 114B is aligned with the third edge E3 of the second stack structure 104B.

In addition, the memory device 200 may further include a source line doped region 118 formed in the substrate 102. In addition, the source line doped region 118 is disposed at the fourth side S4 of the second stack structure 104B. The source line doped region 118 has a second conductive type, and the second conductive type is different from the first conductive type of the substrate 102. For example, in some embodiments of the present disclosure, the first conductive type is P-type, whereas the second conductive type is N-type. However, in other embodiments of the present disclosure, the first conductive type is N-type, whereas the second conductive type is P-type.

Still referring to FIG. 2, in some embodiments of the present disclosure, the source line doped region 118 includes a lightly-doped region 118A disposed in the substrate 102 and a heavily-doped region 118B partially overlapping with the lightly-doped region 118A.

In some embodiments of the present disclosure, the doping concentration of the lightly-doped region 118A is about 10¹¹-10¹³/cm³, for example about 10¹²/cm³. In addition, the doping concentration of the heavily-doped region 118B is greater than 10¹³/cm³, for example about 10¹⁵-10¹⁷/cm³.

In some embodiments of the present disclosure, the source line doped region 118 may be formed by ion implantation. For example, when the second conductive type is N-type, the predetermined region for the source line doped region 118 may be implanted with phosphorous ions or arsenic ions to form the source line doped region 118. In other embodiments of the present disclosure, when the first conductive type is P-type, the predetermined region for the source line doped region 118 may be implanted with boron ion, indium ion or boron difluoride ion (BF₂⁺) to form the source line doped region 118.

Still referring to FIG. 2, in some embodiments of the present disclosure, the lightly-doped region 118A extends under the bottom surface 104BS of the second stack structure 104B. In addition, in some embodiments of the present disclosure, the lightly-doped region 118A may be in direct contact with the bottom surface 104BS of the second stack structure 104B. In some embodiments of the present disclosure, the heavily-doped region 118B partially overlaps with the lightly-doped region 118A. In addition, the depth of the heavily-doped region 118B is greater than the depth of the lightly-doped region 118A.

In addition, in some embodiments of the present disclosure, the heavily-doped region 118B does not extend under the bottom surface 104BS of the second stack structure 104B. In other words, the heavily-doped region 118B does not come into contact with the bottom surface 104BS of the second stack structure 104B. In addition, in some embodiments of the present disclosure, the edge 118BE1 of the heavily-doped region 118B aligns with the fourth edge E4 of the second stack structure 104B.

In this embodiment, due to the second stack structure 104B, the current flows through the first stack structure 104A may be increased. Therefore, it is easier to drive the peripheral circuits.

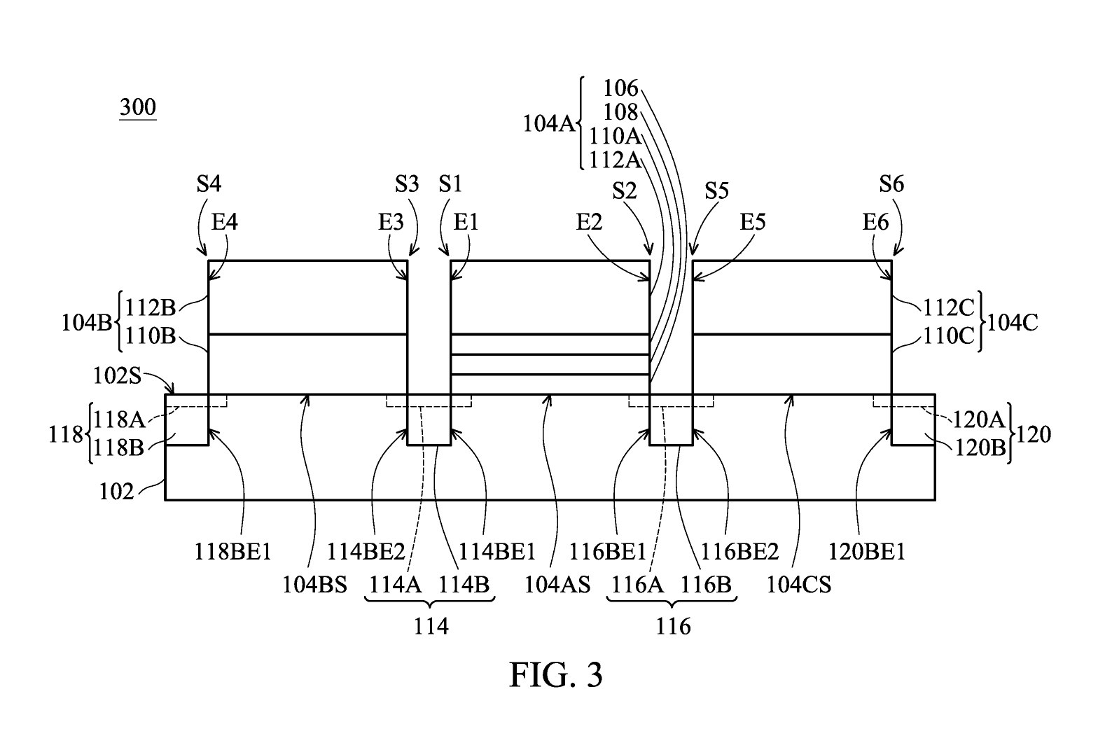

FIG. 3 is a cross-sectional view of a memory device 300 in accordance with some other embodiments of the present disclosure. As shown in FIG. 3, a third stack structure 104C may be formed over the top surface 102S of the substrate 102. In addition, the third stack structure 104C is disposed at the second side S2 of the first stack structure 104A.

As shown in FIG. 3, the third stack structure 104C includes a third silicon oxide layer 110C disposed over the top surface 102S of the substrate 102, and a third gate line 112C disposed over the third silicon oxide layer 110C. The third silicon oxide layer 110C and the third gate line 112C may be formed by steps that are similar to those mentioned above. In other words, in some embodiments of the present disclosure, the third silicon oxide layer 110C may be formed by chemical vapor deposition or spin-on coating. The third gate line 112C may be formed by chemical vapor deposition (CVD), sputtering, resistive thermal evaporation, electron beam evaporation, or any other suitable method.

In addition, in some embodiments of the present disclosure, the thickness of the third silicon oxide layer 110C is substantially equal to the total thickness of the tunneling layer 106, the charge layer 108, and the first silicon oxide layer 110A of the first stack structure 104A.

In addition, the third stack structure 104C has a fifth side S5 and a sixth side S6 opposite to each other. The fifth side S5 faces the second side S2 of the first stack structure 104A. The third stack structure 104C has a fifth edge E5 at the fifth side S5, and has a sixth edge E6 at the sixth side S6.

In addition, in some embodiments of the present disclosure, as shown in FIG. 3, the bit line doped region 116, which is disposed at the second side S2 of the first stack structure 104A, extends from the bottom surface 104AS of the first stack structure 104A to the bottom surface 104CS of the third stack structure 104C. Therefore, in some embodiments of the present disclosure, the bit line doped region 116 also serves as a source line doped region of the third stack structure 104C.

In particular, the lightly-doped region 116A of the bit line doped region 116 extends from the bottom surface 104AS of the first stack structure 104A adjacent to the second side S2 to the bottom surface 104CS of the third stack structure 104C adjacent to the fifth side S5. The lightly-doped region 116A may be in direct contact with the bottom surface 104AS of the first stack structure 104A and the bottom surface 104CS of the third stack structure 104C.

In addition, the heavily-doped region 116B of the bit line doped region 116 does not extend under the bottom surface 104AS of the first stack structure 104A and the bottom surface 104CS of the third stack structure 104C. In other words, the heavily-doped region 116B does not come into contact with the bottom surface 104AS of the first stack structure 104A and the bottom surface 104CS of the third stack structure 104C. In addition, in some embodiments of the present disclosure, one edge 116BE1 of the heavily-doped region 116B is aligned with the second edge E2 of the first stack structure 104A, and the other edge 116BE2 of the heavily-doped region 116B is aligned with the fifth edge E5 of the third stack structure 104C.

In addition, the memory device 300 may further include a bit line doped region 120 formed in the substrate 102. In addition, the bit line doped region 120 is disposed at the sixth side S6 of the third stack structure 104C. The bit line doped region 120 has a second conductive type, and the second conductive type is different from the first conductive type of the substrate 102. For example, in some embodiments of the present disclosure, the first conductive type is P-type, whereas the second conductive type is N-type. However, in other embodiments of the present disclosure, the first conductive type is N-type, whereas the second conductive type is P-type.

Still referring to FIG. 3, in some embodiments of the present disclosure, the bit line doped region 120 includes a lightly-doped region 120A disposed in the substrate 102 and a heavily-doped region 120B partially overlapping with the lightly-doped region 120A.

In some embodiments of the present disclosure, the doping concentration of the lightly-doped region 120A is about 10¹¹-10¹³/cm³, for example about 10¹²/cm³. In addition, the doping concentration of the heavily-doped region 120B is greater than 10¹³/cm³, for example about 10¹⁵-10¹⁷/cm³.

In some embodiments of the present disclosure, the bit line doped region 120 may be formed by ion implantation. For example, when the second conductive type is N-type, the predetermined region for the bit line doped region 120 may be implanted with phosphorous ions or arsenic ions to form the bit line doped region 120. In other embodiments of the present disclosure, when the first conductive type is P-type, the predetermined region for the bit line doped region 120 may be implanted with boron ion, indium ion or boron difluoride ion (BF₂⁺) to form the bit line doped region 120.

Still referring to FIG. 3, in some embodiments of the present disclosure, the lightly-doped region 120A extends under the bottom surface 104CS of the third stack structure 104C. In addition, in some embodiments of the present disclosure, the lightly-doped region 120A may be in direct contact with the bottom surface 104CS of the third stack structure 104C. In some embodiments of the present disclosure, the heavily-doped region 120B partially overlaps with the lightly-doped region 120A. In addition, the depth of the heavily-doped region 120B is greater than the depth of the lightly-doped region 120A.

In addition, in some embodiments of the present disclosure, the heavily-doped region 120B does not extend under the bottom surface 104CS of the third stack structure 104C. In other words, the heavily-doped region 120B does not come into contact with the bottom surface 104CS of the third stack structure 104C. In addition, in some embodiments of the present disclosure, the edge 120BE1 of the heavily-doped region 120B aligns with the sixth edge E6 of the third stack structure 104C.

In this embodiment, due to the third stack structure 104C, the current flows through the first stack structure 104A may be increased. Therefore, it is easier to drive the peripheral circuits.

Still referring to FIGS. 1-3, the memory device 100-300 may include a substrate 102 and a first stack structure 104A disposed over the top surface 102S of the substrate 102. The first stack structure 104A has a first side S1 and a second side S2 opposite to each other, and the first stack structure 104A includes a tunneling layer 106 disposed over the top surface 102S of the substrate 102. The tunneling layer 106 includes SiₓO_{y}N_{z}, and x:y ranges from about 1:0.1 to 1:10, and x:z ranges from about 1:0.1 to 1:10. The first stack structure 104A further includes a charge layer 108 disposed over the tunneling layer 106, a first silicon oxide layer 110A disposed over the charge layer 108 and a first gate line 112A disposed over the first silicon oxide layer 110A. In addition, the memory device 100-300 further includes a source line doped region 114 disposed in the substrate 102 and disposed at the first side S1 of the first stack structure 104A and a bit line doped region 116 disposed in the substrate 102 and disposed at the second side S2 of the first stack structure 104A.

In addition, the memory device 200-300 further includes a second stack structure 104B disposed over the top surface 102S of the substrate 102 and disposed at the first side S1 of the first stack structure 104A. The second stack structure 104B includes a second silicon oxide layer 110B disposed over the top surface 102S of the substrate 102 and a second gate line 112B disposed over the second silicon oxide layer 110B.

In addition, the memory device 300 further includes a third stack structure 104C disposed over the top surface 102S of the substrate 102 and disposed at the second side S2 of the first stack structure 104A. The third stack structure 104C includes a third silicon oxide layer 110C disposed over the top surface 102S of the substrate 102 and a third gate line 112C disposed over the third silicon oxide layer 110C.

In summary, the data storage structure of some embodiments of the present disclosure includes a three-layered structure including a tunneling layer, a charge layer and a silicon oxide layer. In addition, the tunneling layer includes specific material such that the memory device of some embodiments of the present disclosure (such as a non-volatile memory device) may further decrease the programming voltage (or write voltage), improve the program speed (or write speed) and lengthen the data storage time.

In addition, it should be noted that the bit line doped region and source line doped region mentioned above in the present disclosure are switchable since the definition of the drain and source is related to the voltage connecting thereto.

Note that the above element sizes, element parameters, and element shapes are not limitations of the present disclosure. Those skilled in the art can adjust these settings or values according to different requirements. It should be understood that the memory device and method for manufacturing the same of the present disclosure are not limited to the configurations of FIGS. 1 to 3. The present disclosure may merely include any one or more features of any one or more embodiments of FIGS. 1 to 3. In other words, not all of the features shown in the figures should be implemented in the memory device and method for manufacturing the same of the present disclosure.

In addition, although the doping concentrations of various doped region in some embodiments have been described previously, one skilled in the art will recognize, however, that the doping concentrations of various doped region depend upon the specific device type, technology generation, minimum feature size, and the like. It is intended, therefore, that the doping concentrations of various doped region may be interpreted in light of the technology being evaluated and not be limited to the described embodiments.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and operations described in the specification. As one of ordinary skill in the art will readily appreciate from the disclosure of the present disclosure, processes, machines, manufacture, compositions of matter, means, methods, or operations, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or operations.

1. A memory device, comprising:
a substrate;
a first stack structure disposed over a top surface of the substrate, wherein the first stack structure has a first side and a second side opposite to each other, and the first stack structure comprises:
a tunneling layer disposed over the top surface of the substrate, wherein the tunneling layer is SiₓN_{z}, wherein x:z ranges from about 1:0.1 to 1:10;
a charge layer disposed over the tunneling layer;
a first silicon oxide layer disposed over the charge layer; and
a first gate line disposed over the first silicon oxide layer;
a source line doped region disposed in the substrate and adjoining the first stack structure at the first; and
a bit line doped region disposed in the substrate and adjoining the first stack structure at the second side;
a second stack structure disposed over the top surface of the substrate and adjoining the source line doped region, wherein the second stack structure comprises:
a second silicon oxide layer disposed over the top surface of the substrate; and
a second gate line disposed over the second silicon oxide layer; and
a third stack structure disposed over the top surface of the substrate and adjoining the bit line doped region, wherein the third stack structure comprises:
a third silicon oxide layer disposed over the top surface of the substrate; and
a third gate line disposed over the third silicon oxide layer.

2. The memory device as claimed in claim 1, wherein
the second stack structure is disposed at the first side of the first stack structure.

3. The memory device as claimed in claim 1, wherein the source line doped region, which is disposed at the first side of the first stack structure, extends from a bottom surface of the first stack structure to a bottom surface of the second stack structure.

4. The memory device as claimed in claim 1, wherein
the third stack structure is disposed at the second side of the first stack structure.

5. The memory device as claimed in claim 1, wherein the bit line doped region, which is disposed at the second side of the first stack structure, extends from a bottom surface of the first stack structure to a bottom surface of the third stack structure.

6. The memory device as claimed in claim 1, wherein the charge layer comprises SiₐN_{b}, wherein a:b ranges from about 1:0.1 to 1:10.

7. The memory device as claimed in claim 6, wherein x:z is not equal to a:b.

8. The memory device as claimed in claim 1, wherein a thickness of the tunneling layer ranges from about 2 nm-200 nm.

9. The memory device as claimed in claim 1, wherein the substrate has a first conductive type, and the source line doped region and the bit line doped region have a second conductive type, wherein the first conductive type is different from the second conductive type.

10. The memory device as claimed in claim 1, wherein each of the source line doped region and the bit line doped region independently comprises:
a lightly-doped region disposed in the substrate; and
a heavily-doped region partially overlapping with the lightly-doped region.

11. A method for manufacturing a memory device, comprising:
providing a substrate;
forming a first stack structure over a top surface of the substrate, wherein the first stack structure has a first side and a second side opposite to each other, and the first stack structure comprises:
a tunneling layer disposed over the top surface of the substrate, wherein the tunneling layer is SiₓN_{z}, wherein x:z ranges from about 1:0.1 to 1:10;
a charge layer disposed over the tunneling layer;
a first silicon oxide layer disposed over the charge layer; and
a first gate line disposed over the first silicon oxide layer;
forming a source line doped region in the substrate, wherein the source line doped region adjoins the first stack structure at the first side; and
forming a bit line doped region in the substrate, wherein the bit line doped region adjoins the first stack structure at the second side;
forming a second stack structure over the top surface of the substrate and adjoining the source line doped region, wherein the second stack structure comprises:
a second silicon oxide layer disposed over the top surface of the substrate; and
a second gate line disposed over the second silicon oxide layer; and
forming a third stack structure over the top surface of the substrate and adjoining the bit line doped region, wherein the third stack structure comprises:
a third silicon oxide layer disposed over the top surface of the substrate; and
a third gate line disposed over the third silicon oxide layer.

12. The method for manufacturing the memory device as claimed in claim 11, wherein
the second stack structure is disposed at the first side of the first stack structure.

13. The method for manufacturing the memory device as claimed in claim 11, wherein the source line doped region, which is disposed at the first side of the first stack structure, extends from a bottom surface of the first stack structure to a bottom surface of the second stack structure.

14. The method for manufacturing the memory device as claimed in claim 11, wherein
the third stack structure is disposed at the second side of the first stack structure.

15. The method for manufacturing the memory device as claimed in claim 11, wherein the bit line doped region, which is disposed at the second side of the first stack structure, extends from a bottom surface of the first stack structure to a bottom surface of the third stack structure.

16. The method for manufacturing the memory device as claimed in claim 11, wherein the charge layer comprises SiₐN_{b}, wherein a:b ranges from about 1:0.1 to 1:10.

17. The method for manufacturing the memory device as claimed in claim 16, wherein x:z is not equal to a:b.

18. The method for manufacturing the memory device as claimed in claim 11, wherein a thickness of the tunneling layer ranges from about 2 nm-200 nm.

19. The method for manufacturing the memory device as claimed in claim 11, wherein the substrate has a first conductive type, and the source line doped region and the bit line doped region have a second conductive type, wherein the first conductive type is different from the second conductive type.

20. The method for manufacturing the memory device as claimed in claim 11, wherein each of the source line doped region and the bit line doped region independently comprises:
a lightly-doped region disposed in the substrate; and
a heavily-doped region partially overlapping with the lightly-doped region.
